(19) United States
(12) Patent Application Publication
(10) Pub. No.: US 2017/0192039 A1
(43) Pub. Date: Jul. 6, 2017

(54) CURRENT-DETECTION DEVICE

(71) Applicant: THALES, Courbevoie (FR)

(72) Inventors: Emmanuel Desurvire, Palaiseau (FR); Jean-Paul Castera, Palaiseau (FR); Bertrand Demotes-Mainard, Neuilly-sur-Seine Cedex (FR)

(21) Appl. No.: 15/314,958

(22) PCT Filed: May 29, 2015
(86) PCT No.: PCT/EP2015/062041

§ 371 Date: Nov. 30, 2016

(30) Foreign Application Priority Data
May 30, 2014 (FR) 1401254

(51) Int. Cl. G01R 15/20; G01R 33/035

(52) U.S. Cl. CPC G01R 15/20; G01R 33/035

(57) ABSTRACT

This current detection device (300) is characterized in that it includes:
a first conductor wire (306) in which flows an external current (iₑₓₜ) to be measured, the first wire generating in its vicinity an external magnetic field (Bₑₓₜ);
a magnetometric sensor (310) placed in the vicinity of the first conductor wire, sensitive to a flux of the external magnetic field and able to generate a measurement signal corresponding to the external current.

The invention is in the field of current detection devices.

In the general field of microelectronics and of signal processing, it is necessary to be able to detect electric currents varying over time. For example, an important application is formed by current amplification. Another important application is formed by current regulation, in order to notably avoid several deleterious effects, such as intensity drift (lowering or increasing random fluctuations) or transient intensity jumps (highly intense and short-lived drops or increases).

Many techniques for detecting current exist, which are based on the principle of a real time measurement of the intensity of a current derived from the current circulating in the main conductor, the derived current crossing a calibrated resistor, which has a high value so that the measurement do not affect or only very little the main current. The measurement of the voltage v(t) on the terminals of this resistor is proportional to the main current i(t).

Such a device operates very well under DC conditions (DC).

On the other hand, under alternating current conditions (AC), the main source of limitation is formed by the impedance of the branch circuit, which limits the extension of the passband width to high frequencies.

Further, the spectral response of the branch circuit is not uniform.

Wide and uniform passband widths are characteristics which are difficult to obtain simultaneously.

It should be emphasized that imperfections of the spectral response may introduce a time distortion of the shunt current, which may be coupled with the remainder of the circuit, for example altering the main current, which is particularly bothersome for the purity of analogue RF signals, or may radiate parasitic electromagnetic (EM) waves, which may be bothersome for the operation of neighboring components.

The object of the invention is therefore to overcome this problem notably by proposing an improved current detection device.

For this purpose, the object of the invention is a current detection device characterized in that it includes: a first conductive wire in which flows an external current to be measured, the first wire generating in its vicinity an external magnetic field; a magnetometric sensor placed in the vicinity of the first conductive wire, sensitive to a flux of the external magnetic field and able to generate a measurement signal corresponding to the external current.

Advantageously, the current detection device is a wide-band device, i.e. it has a high cutoff frequency; it has a uniform response, on this passband width; and generates at the output a current having a higher intensity than the measured shunt current, i.e. it amplifies the current to be measured. According to particular embodiments, the current detection device includes one or several of the following features, taken individually or according to all the technically possible combinations:

- the magnetometric sensor includes: a magnetic sensor having a surface and generating a response signal when it is immersed in a magnetic field generating a magnetic flux through said surface; a control circuit, taking as an input the response signal of the magnetometer and generating at the output a feedback current; and, a second conductor wire positioned in the vicinity of the magnetic sensor and connected at the output of the control circuit, the wire being crossed by the feedback current, the circuit and the conductive wire being such that a feedback magnetic field is generated, the flux of which through the surface of the magnetic sensor substantially compensates at each instant for the flux of the external magnetic field, the output signal of the measuring device being formed by the feedback current;

- the magnetic sensor is a superconducting magnetic sensor;

- the control circuit includes a comparison means able to compare the response signal of the magnetic sensor with a reference signal and to generate a comparison signal, and a current source controlled by the comparison signal, able to generate the feedback current;

- the detection device has an extended passband width and a linear and uniform response on said passband width;

- the magnetic sensor consists of a plurality of elementary magnetic sensors connected in series between the input terminals of the control circuit;

- the first and second conductive wires are conformed so as to progress in parallel in a plane of the surface of the magnetic sensor, the outer current circulating in a first direction and the feedback current circulating in a second direction opposite to the first;

- the first wire or the second wire form a loop around the surface of the magnetic sensor, the loop including at least one turn;

- the magnetic sensor consisting of a plurality of elementary magnetic sensors connected in series between the input terminals of the control circuit, the first and second wires forming a plurality of meanders around a plurality of elementary magnetometers;

- as the elementary magnetic sensors are asymmetrical, the elementary magnetic sensors are positioned in one meander out of two, or, as said elementary magnetic sensors are symmetrical, the elementary magnetic sensors are positioned in each meander;

- the magnetometric sensor and a portion of the first conductive wire are placed in a case allowing magnetic isolation relatively to the outside world.

The invention and advantages thereof will be better understood upon reading the description which follows of embodiments and of use, exclusively given as an example, and made with reference to the appended drawings wherein:

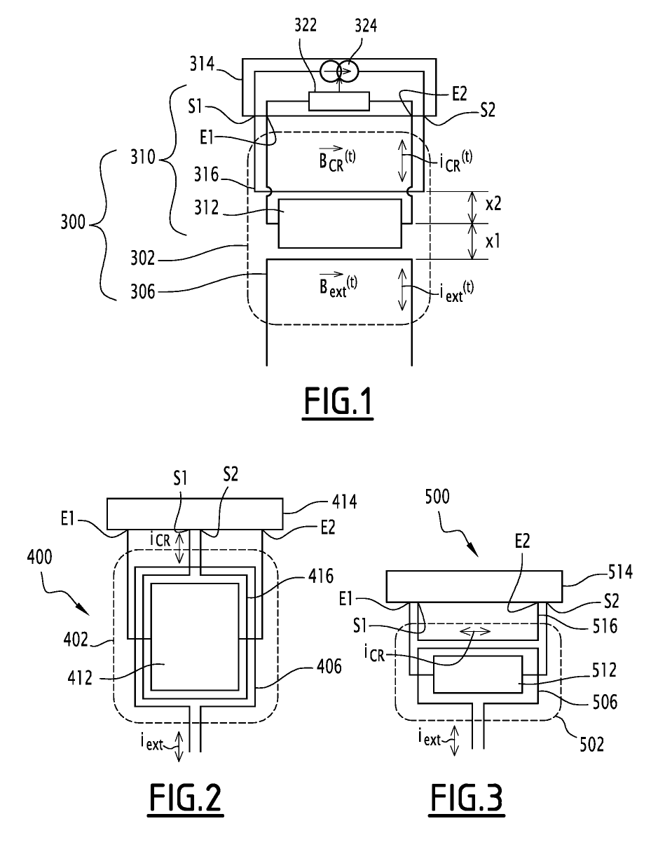

FIG. 1 is a block diagram illustration of a current measuring device;

FIG. 2 is a schematic illustration of an embodiment said to be in a loop of the device of FIG. 1;

FIG. 3 is a schematic illustration of a so called intermediate embodiment of the device of FIG. 1;

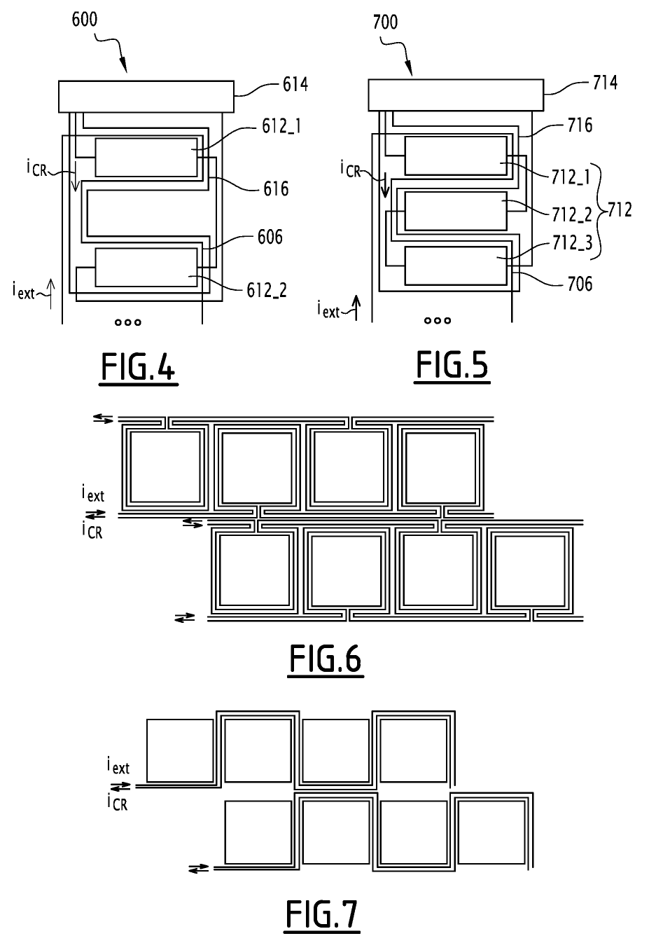

FIG. 4 is a schematic illustration of a so called meander embodiment of the device of FIG. 1, applying asymmetrical magnetic sensors;

FIG. 5 is a schematic illustration of a so called meander embodiment of the device of FIG. 1, applying symmetrical magnetic sensors;

FIG. 6 is a simplified illustration of a dense two-dimensional integration of so called looped embodiments; and,

FIG. 7 is a simplified illustration of a dense two-dimensional integration of so called meander embodiments.

In FIG. 1 is illustrated a current detection device 300.

The device 300 includes a case 302, a first conductive wire 306 and a magnetic sensor 310.

The case 302 delimits a cavity which is magnetically isolated from the outside world, in particular from the Earth's magnetic field or from perturbing magnetic fields, like those by generated by radioelectric waves. The case 302 is in a suitable material able to screen these outer fields.

The first conductive wire 306 circulates from the outside, into the cavity delimited by the case 302. The wire 306 is crossed by the external current, iₑₓₜ, to be measured. When the external current iₑₓₜ circulates in the wire 306, it generates an external magnetic field Bₑₓₜ around the wire 306, in particular inside the case 302. The external field Bₑₓₜ is linear relatively to the external current iₑₓₜ. The external current iₑₓₜ(t) varies over time t. The same also applies to the external magnetic field Bₑₓₜ(t).

The magnetometric sensor 310 is able to measure the external magnetic field Bₑₓₜ(t) inside the case 302 in order to indirectly obtain a measurement of the current iₑₓₜ(t).

The magnetometric sensor 310 includes a magnetic sensor 312, a control circuit 314 and a conductor wire 316.

A magnetic sensor 312 includes a component sensitive to the magnetic field, which is able to issue, as a voltage or as a current, a measurement signal V corresponding to the magnetic field in which it is immersed.

Among magnetic sensors, optical magnetic sensors are known such as sensors with diamond N-V centers, wherein the transition between two energy levels of the electrons of an atom forming an impurity in a crystal is modified when this crystal is immersed in an external magnetic field Bₑₓₜ. The modification of the transition modifies the response of the crystal illuminated by a suitable laser light. Such a magnetic sensor operates at room temperature.

The response of the crystal is linear but over a reduced range of frequencies around a characteristic frequency of the transition width used.

From among magnetic sensors, supraconductive magnetic sensors are also known, which are of particular interest, since they provide the highest physically attainable sensitivities. Such a magnetic sensor, applying superconducting materials, operates at low temperatures, around about 80 K for superconducting materials said to have a high critical temperature, or ultra-low temperature supraconducting materials around about one milli-Kelvin for so called critical low temperature supraconducting materials.

A superconducting magnetic sensor is a SQUID component (for “Superconducting Quantum Interference Device”) or a SQIF component (for “Superconducting Quantum Interference Filter”). A SQIF component consists of a matrix of SQUID components, connected in series, in parallel or both.

Because of their operating principles, SQUID and SQIF components have a non-linear response, i.e. the voltage V(φ) induced by the flux φ of the external magnetic field Bₑₓₜ crossing a surface S of the component, is not a linear function of the flux φₑₓₜ, and therefore of the external magnetic field Bₑₓₜ.

In the case of a SQUID component, this response is a sign-wave. In the region of the inflexion point of the sign-wave, the behavior to the first order is linear. However, this region corresponds to a relatively narrow flux range.

In the case of a SQIF component, the response is uniform, V(φ)=cste, except around certain characteristic points, periodically positioned, for which the flux φₑₓₜ of the external magnetic field Bₑₓₜ is equal to an integer number of times a characteristic flux φ₀, a so-called <<fluxon>>. Thus, the response of a SQIF component assumes the shape of a <<reversed comb>>.

In a modified SQIF component, having a particular configuration, the response is uniform except in a region around the origin, φₑₓₜ=0, wherein this response is canceled out. In this region, the response, symmetrical around the origin, is quasi-linear. However, this region corresponds to a relatively narrow flux range.

The magnetic sensor 312 is a superconducting magnetic sensor.

The magnetic sensor 312 is of a rectangular parallelepipedal shape. It has a small thickness and an active surface S, substantially planar and having a normal in the direction of the thickness of the magnetic sensor.

The magnetic sensor 312 is able to generate, between its two output terminals, a response signal, which here is a voltage V. The voltage V is a function of the total instantaneous magnetic flux φ(t) through the surface S.

The control circuit 314 receives between its two input terminals, E1 and E2, the response signal V(φ)(t)) produced by the magnetic sensor 312, and generates a feedback current i_{CR}(t) between its two output terminals, S1 and S2.

More specifically, the control circuit 314 includes a comparison means 22 connected to the input terminals E1 and E2, and able to compare the response signal V(φ)(t)) with a reference signal V₀ and to generate a comparison signal.

The control circuit 314 includes a current source 24 controlled by the comparison signal and able to generate, between both output terminals, the feedback current i_{CR}(t).

The conductor wire 316 is connected between the output terminals S1 and S2 of the control circuit 314. It is conformed in order to circulate in the vicinity of the magnetic sensor 312. The conductive wire 316 is crossed by the feedback current i_{CR}(t). Consequently, it generates around it a feedback magnetic field B_{CR}(t). The field B_{CR}(t) is linear relatively to the current i_{CR}(t). The field B_{CR}(t) generates a feedback flux φ_{CR}(t) through the surface S of the magnetic sensor 312: φ_{CR}(t)=B_{CR}(t).S

At each instant, the response signal V(t) delivered by the magnetic sensor 312 depends on the total magnetic flux φ(t) crossing the surface S.

This total flux φ(t) is the sum of the external flux φₑₓₜ(t), which results from the external magnetic field Bₑₓₜ(t) to be measured according to the relationship φₑₓₜ(t)=Bₑₓₜ(t).S, and from the feedback flux φ_{CR}(t).

The sensor 310 is at equilibrium when the total flux φ(t) received by the magnetic sensor 312 is constant. Under these conditions, permanently forced by the instantaneous feedback, the feedback current i_{CR}(t) represents a linear measurement of the external magnetic field Bₑₓₜ(t).

In order that this equilibrium exists, the geometrical and physical parameters of the sensor 310 are selected so that the feedback flux is opposite to the external flux and that the response V(t) of the magnetic sensor 312 may be instantaneously reduced to the reference voltage V₀. In other words, the control circuit 314 and the conductive wire 316 are such that a feedback magnetic field is generated, the flux of which through the active surface of the magnetic sensor substantially compensates at each instant, for the flux of the external magnetic field.

It should be noted that if the external magnetic field Bₑₓₜ has a DC component, the stabilization point will be the reference voltage V₀ shifted by a constant.

By suitably selecting the reference voltage V₀, the maximum sensitivity of the sensor 310 is obtained for the response area of the magnetic sensor 312 wherein the derivative

$$\frac{\partial V}{\partial φ}$$

is maximum. For a superconducting magnetic sensor of the SQUID type, this corresponds to the inflexion point of the sign-wave response. For a superconducting magnetic sensor of the modified SQIF type, this corresponds to the point of origin, optionally slightly shifted for avoiding ambiguities on the sign of the field and therefore on that of the current due to the symmetrical response of such a magnetic sensor.

It should be emphasized that in the magnetometric sensor 310, the response signal of the magnetic sensor 312 is not considered as a measurement signal, but as a regulation signal for a feedback loop. It is the feedback signal which forms the measurement signal.

Thus, the current detection device has great sensitivity, a linear and uniform behavior over an extended passband width, by limiting the operation of the magnetic sensor in the narrow region where it has great sensitivity and a linear behavior.

Advantageously, in order that the sensor has good sensitivity, because of the circular shape of the magnetic field lines around a wire in which flows a current, the first and second wires 306 and 316 are positioned in the plane P of the surface S of the magnetic sensor 312.

Further, in the case when the external current does not have any DC component and when the first and second wires 306 and 316 are located perfectly symmetrically around the magnetic sensor 312, the feedback current is, at each instant, the exact counterpart of the external current to be measured: i_{CR}(t)=iₑₓₜ(t).

It is possible to introduce a current amplification factor, defined by:

G=|i_{CR}(t)|/|iₑₓₜ(t)|,

by selecting a geometry wherein the second wire 316 is placed at a distance x2 from the center of the magnetic sensor 312 which is greater than the distance x1 at which the first wire 306 is placed from the center of the magnetic sensor 312.

FIG. 1 illustrates an embodiment wherein the first and second wires 306 and 316 are rectilinear and positioned on either side of the magnetic sensor 312.

Other embodiments may be contemplated.

Thus, in FIG. 2, the detection device 400 has a looped configuration. An element of the device of FIG. 2 either identical with or similar to a corresponding element of the device of FIG. 1 is located with the same reference number as this corresponding element increased by one hundred.

The first wire 406 is conformed so as to form a first loop around the magnetic sensor 412. The latter then measures a flux φₑₓₜ(t) induced by a current loop, rather than by a rectilinear conductive wire. By assuming a circular loop, a multiplicative factor equal to π is thereby introduced between the rectilinear configuration of FIG. 4 and the loop configuration.

Further, by conforming the first wire 406 so that the first loop includes N1>1 turns, the external flux φₑₓₜ(t) through the surface S is multiplied by a factor N1.

The introduction of these multiplicative factors gives the possibility of increasing the sensitivity of the device 400 as compared with that of the device 300.

The second wire 416 is also advantageously conformed so as to form a second loop including N2 turns.

With first and second loops of the same diameter, an integer amplification factor G is obtained in a simple way by selecting a configuration wherein N is equal to G and N2 to 1. More generally, an integer amplification factor G is obtained simply by selecting:

$$\frac{N 2}{N 1} = G .$$

This loop configuration has a wide-band response.

The passband width is limited at the high frequencies mainly by an effect of radiative resistance, R_{rad}, which is proportional to f⁴, wherein f is the frequency of the feedback current i_{CR}. The radiative resistance supersedes here on another limitation which is due to the inductance of the loop formed by the wire 416, this inductance being proportional to f.

By reducing the dimensions of the circuit formed by the conductive wire 416, the radiative resistance R_{rad} may be reduced so as to push back as far as possible the high cutoff frequency of the sensor 410.

Another drawback is that the first loop induces a “parasitic”>current i_{ind}(t) in a second loop, according to the law:

$$Z . {i}_{ind} ( t ) = - e \frac{\partial {φ}_{ext} ( t )}{\partial t}$$

Wherein Z is the impedance of the second feedback loop.

Both loops thus behave like a current transformer, and i_{ind}(t) represents a measurement of the external current iₑₓₜ(t).

In order to utilize the property of the magnetic sensor, the control circuit 414 is then adapted so as to generate a feedback current such that:

i_{CR}(t)=2.i_{ind}(t)

The feedback current is injected into the second wire so as to circulate in the direction opposite to that of the induced current.

This has the effect of exactly canceling out (to within a constant) the total flux in the magnetic sensor 412 and therefore to properly servo-control the feedback current.

The loop configuration allows dense integration in one or two dimensions into the plane P, as this is schematically illustrated in FIG. 6.

This loop configuration gives the possibility of making a magnetic sensor with reduced dimensions.

In FIG. 3, a detection device 500 is illustrated, which is an intermediate embodiment between the devices 300 and 400. An element of the device of FIG. 3 either identical with or similar to an element corresponding to the device of FIG. 1 is located with the same reference number as this corresponding element increase by about two hundred.

In this embodiment, if the first wire 506 is conformed into a first loop, the second wire 516 is rectilinear.

The advantage here is to allow removal of the induced parasitic current i_{ind}(t) in the second wire by the first wire in the device 400. The impedance of the magnetometric sensor 510 is then strongly reduced, while retaining significant sensitivity because of the π. N1 factor of the first loop relatively to the configuration wherein both wires are rectilinear (FIG. 1).

Another advantage of this intermediate configuration lies in the fact that for exactly compensating the external flux, it is necessary to apply a feedback current which has a π times larger intensity than the intensity of the feedback current of the device 400. Thus, the total gain on the feedback current, i.e. the measurement current, is here: G=π².N1, i.e. for example G=100 for N=10.

FIGS. 4 and 5 illustrate two detection devices according to a meander embodiment.

An element of the device of FIG. 4 either identical or similar to a corresponding element of the device of FIG. 1 is located with the same reference number as this corresponding element increased by three hundred.

In device 600, the magnetic sensor 612 consists of a plurality of elementary magnetic sensors 612-i, which are positioned along a row, so that their respective surfaces Si are in the same plane P. The elementary sensors 612-i are connected in series between the input terminals E1 and E2 of the control circuit 614.

The first and second wires 606 and 616 are conformed so as to progress in parallel to each other in the plane P. They are separated from each other by a reduced pitch relatively to their respective widths.

The conductive wires 606 and 616 are configured so as to circulate between two elementary magnetic sensors 612-i by forming a meander.

The external current iₑₓₜ(t) is applied in the first wire 606 so as to circulate in one direction and the feedback current i_{CR}(t) is applied in the second wire 616 so as to circulate in the other direction.

The magnetic field generated by a wire has, in the plane P of the surfaces Si of the elementary magnetic sensors, an orientation along the direction normal to the plane P, which is positive on one side of the wire and negative on the other side of the wire.

In the device 600, the elementary magnetic sensors 612-i are asymmetrical, their response being such that: V(−φ)=−V(φ). For example this is a SQUID. The elementary magnetic sensors 612-i of one meander out of two have them to be spaced out, so that the responses of the elementary magnetic sensors do not cancel out two by two considering the inversion of the orientation of the external and feedback magnetic fields from one meander to the other.

An element of the device of FIG. 5 either identical or similar to a corresponding element of the device of FIG. 1 is located with the same reference number as this corresponding element increased by four hundred.

In the device 700 of FIG. 5, moreover everything being equal relatively to the device 600 of FIG. 4, the elementary magnetic sensors 712-i are symmetrical, their response being such that: V(−φ)=V(φ). For example this is the case of the superconducting magnetic sensors of the SQIF type. Their response is independent of the direction of the magnetic field, elementary magnetic sensors 712-i may then be advantageously placed in each of the meanders defined by the first and second wires 706 and 716. The density of elementary magnetic sensors may thus be increased, which at constant surface gives the possibility of increasing the sensitivity of the current measuring device.

The meander configuration introduces a parasitic inductance and a parasitic radiative resistance, whence a limitation of the passband width. However, the meander configuration is characterized by an inductance and a radiative resistance which are intrinsically smaller than that of the loop configuration, which gives the possibility of farther pushing forward the high cutoff frequency of the passband width of the current detection device.

There again, by selecting very small dimensions for the circuit formed by the wire 616 or 716, the radiative resistance may be reduced so as to push further forward the high cutoff frequency of the sensor.

Further, it is possible to optimize the geometrical parameters. For example, the distance x between the second wire 616, 716 respectively, and the axis of the magnetic sensors 612-i may be increased. The magnetic field generated by a wire being reduced by 1/x, in order to obtain the same feedback flux, then needs an increase in the feedback current. This has the advantage of allowing detection of external magnetic fields of very low amplitude (along the normal to the surface Si of the magnetic sensors), i.e. of an external current of low amplitude, by the use of the feedback current of high intensity.

This meander configuration allows dense integration in one or two dimensions in the plane P, as this is schematically illustrated in FIG. 7.

This meander configuration gives the possibility of making a current detection device with reduced dimensions.

The meander configuration is moreover more advantageous than the loop configuration, since it is simpler to optimize and to integrate at a large scale.

The current detection device according to the invention has a wide passband width on which, when the magnetic sensor is of the superconductor type, it has very high sensitivity. By suitably designing the magnetometric sensor, it is possible to contemplate a passband width extending from very low frequency (VLF) to ultra-high frequency (UHF), i.e. between about a few kHz and about 1,000 MHz.

The current detection device also has an intrinsically linear response relatively to the intensity of the external current to be measured. Further, this response is uniform over the whole passband width, i.e. it is independent of the frequency of the external current to be measured.

In terms of measurable intensity of the external current, the current detection device may be adapted: segmentation into domains of feedback current of the control circuit, optimized dimensioning of the loop/meander circuit of both conductive wires, multi-scale integration, etc.

Optionally, pass-band filers may be introduced into the control circuit, in order to specify a certain number of frequency ranges for use, either by order of frequency magnitude of the external current to be measured, or by frequency domains of interest.

The current detection device finally provides the possibility of high-density planar integration.

1. A current detection device, including:
a first conductive wire in which flows an external current to be measured, the first wire generating in a vicinity thereof an external magnetic field;
a magnetometric sensor placed in the vicinity of the first conductor wire, sensitive to a flux of the external magnetic field and generating a measurement signal corresponding to the external current.

2. The current detection device according to claim 1, wherein the magnetometric sensor includes:
a magnetic sensor having a surface and generating a response signal when said magnetic sensor is immersed in a magnetic field generating a magnetic flux through said surface;
a control circuit, taking as an input the response signal of the magnetometer and generating at an output a feedback current; and,
a second conductive wire positioned in the vicinity of the magnetic sensor and connected at the output of the control circuit, the second conductive wire being crossed by the feedback current,
the control circuit and the second conductive wire being such that a feedback magnetic field is generated, a flux of which through the surface of the magnetic sensor substantially compensates, at each instant, for the flux of the external magnetic field,
an output signal of the current detection device being formed by the feedback current.

3. The current detection device according to claim 2, wherein the magnetic sensor is a superconducting magnetic sensor.

4. The current detection device according to claim 2, wherein the control circuit includes a comparison module comparing the response signal of the magnetic sensor relatively to a reference signal and to generating a comparison signal, and a current source controlled by the comparison signal, the current source generating the feedback current.

5. The current detection device according to claim 2, wherein the magnetic sensor is formed with a plurality of elementary magnetic sensors connected in series between the input terminals of the control circuit.

6. The current detection device according to claim 2, wherein the first and the second conductive wires are conformed so as to progress in parallel in a plane of the surface of the magnetic sensor, the external current circulating in a first direction and the feedback current circulating in a second direction opposite to the first direction.

7. The current detection device according to claim 2, wherein the first conductive wire and/or the second conductive wire form a loop around the surface of the magnetic sensor, the loop including at least one turn.

8. The current detection device according to claim 2, wherein the magnetic sensor being formed with a plurality of elementary magnetic sensors connected in series between the input terminals of the control circuit, the first and second conductive wires form a plurality of meanders around the elementary magnetic sensors.

9. The current detection device according to claim 8, wherein said elementary magnetic sensors being symmetrical, the elementary magnetic sensors are positioned in one meander out of two, or, said elementary magnetic sensors being symmetrical, the elementary magnetic sensors are positioned in each meander.

10. The current detection device according to claim 1, having an extended passband width and a linear and uniform response on said passband width.

11. The current detection device according to claim 1, wherein the magnetometric sensor and a portion of the first conductor wire are placed in a case allowing a magnetic isolation towards the outside world.
